(19) United States
(12) Patent Application Publication
(10) Pub. No.: US 2018/0372784 A1
(43) Pub. Date: Dec. 27, 2018

(54) METHOD TO TEST A STATE OF AN ELECTRICAL SYSTEM OF A MOTOR VEHICLE

(71) Applicant: FORD GLOBAL TECHNOLOGIES, LLC, Dearborn, MI (US)

(72) Inventors: Ekkehard POFAHL, Kuerten (DE); Christoph ARNDT, Moerlen (DE); Ulrich SCHMOLL, Bergheim NRW (DE)

(73) Assignee: FORD GLOBAL TECHNOLOGIES, LLC, Dearborn, MI (US)

(21) Appl. No.: 16/017,916

(22) Filed: Jun. 25, 2018

(30) Foreign Application Priority Data
Jun. 27, 2017 (DE) 10 2017 210 827.4

(51) Int. Cl. G01R 31/00; B60R 16/03; G07C 5/08; G07C 5/00

(52) U.S. Cl. CPC G01R 31/007; B60R 16/03; G07C 5/006; G07C 5/0825; G07C 5/085; G07C 5/0808

(57) ABSTRACT

The disclosure relates to a method to test a state of an electrical system, in particular, of an electrical energy supply system, of a motor vehicle. In order to permit electronically automated testing of a state of the electrical system, or the system components of the motor vehicle, during testing of at least one electrical component of the system, at least one electrical property of this electrical component is detected electronically during variation of at least one electrical property of at least one further electrical component of the system. The individual electrical components of the system are detected electronically, and a deterministic test sequence to sequentially test the individual electrical components on the basis of the electrical components present is generated electronically, in which the test sequence is carried out electronically in an automated fashion.

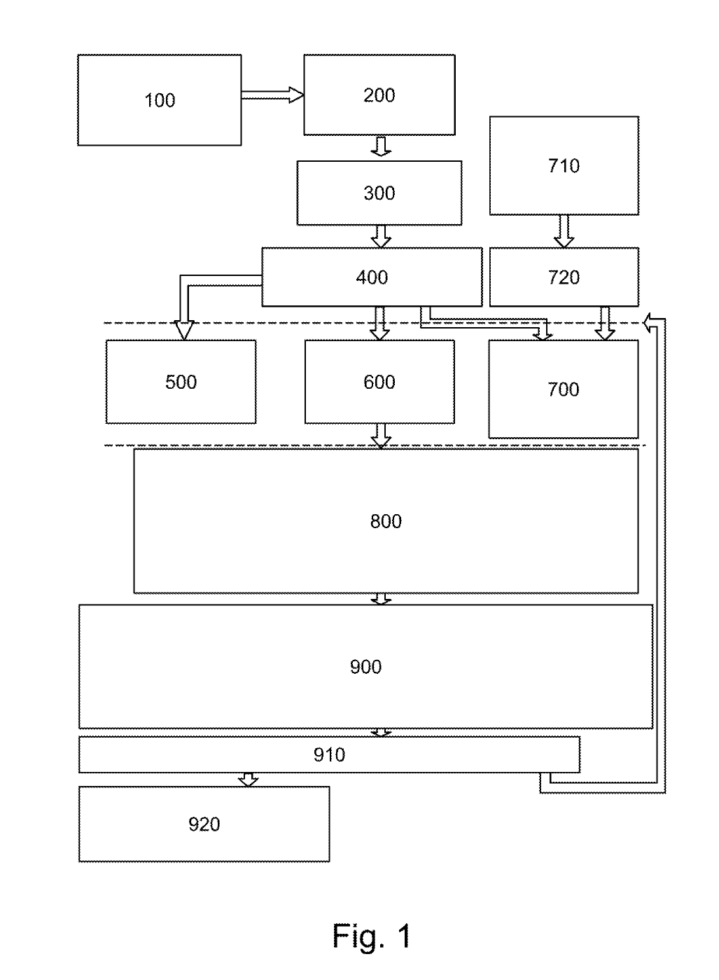

### CROSS-REFERENCE TO RELATED APPLICATIONS

This application claims foreign priority benefits under 35 U.S.C. § 119(a)-(d) to DE Application 10 2017 210 827.4 filed Jun. 27, 2017, which is hereby incorporated by reference in its entirety.

### TECHNICAL FIELD

The disclosure relates to a method to test a state of an electrical system, in particular of an electrical energy supply system, of a motor vehicle.

### BACKGROUND

Contemporary electrical systems of motor vehicles have an ever-increasing degree of complexity. This makes it all the more costly and difficult to determine a location of faults in such electrical systems. The complexity of the electrical system and interactions between different electrical components of the system are frequently difficult to analyze. Such interactions do not need to be deterministic but can easily be defined interactions between electrical components. However, the interactions can also be of the kind that should not occur, such as, for example, an undesired communication between electrical components, wireless or cable-bound, as a result of crosstalk or as a result of fluctuations in the voltage in case of increased switch-on currents. Further interactions would also be faulty or unnecessary interrogations/communications in operating states in which a battery voltage actually has to be limited. Costs of guarantees of automobile manufacturers are directly connected to the capacity to detect faults in the complex electrical systems as early as possible.

Since, in particular, electrical energy supply systems of motor vehicles are of very complex design and individual diagnosis of each individual component of such energy supply systems is very difficult, the diagnosis of customer complaints should be automated. The complexity of an energy supply system becomes apparent, in particular, from the fact that voltage levels, battery charging strategies and rated values for dynamos change within milliseconds during an ignition cycle or driving cycle of the motor vehicle. These changes also occur in the state of rest of the vehicle, but without influencing the dynamo. A high level of specialist ability is necessary to interpret parameters of an energy supply system, which should conventionally be measured manually.

Batteries of a motor vehicle are usually, conventionally tested outside the motor vehicle using very intricate charging/test systems. These charging/test systems carry out a sequence of charging and discharging processes in order to determine a state of a battery.

Furthermore, dynamos (electrical generators, DC/DC converters in hybrids), which are open-loop and/or closed-loop, controlled by an LIN bus, permit only a certain degree of diagnosis. Modern dynamos, which are open-loop and/or closed-loop, controlled by an LIN bus, can detect specific faults and communicate these faults via the LIN bus. PWM open-loop and/or closed-loop controlled dynamos do not permit such diagnostics.

U.S. Pat. No. 4,843,575 A discloses a dynamic real-time management system with a microprocessor, which is adapted to detect real-time inputs that relate to a state of an electrical system. Manual inputs are made available to a processing program, and a long-term memory is included. The memory stores historical data that relates to the real-time inputs, and the microprocessor compares the detected real-time parameters with historical data in order to determine changes of specific unknown operating parameters. The information that is generated in the microprocessor is transmitted to a central microprocessor, which is contained in a central management device. In this way, managers have direct access to information that is generated in one or more electrical systems, in order to permit the managers to make reasonable logical management decisions, so as to remedy costly inefficiencies quickly and reliably.

U.S. Pat. No. 5,450,321 A discloses a dynamic, real-time management system for a motor vehicle, having a microprocessor to detect real-time parameters that relate to a state of the motor vehicle. A plurality of input sensors are connected to components of the motor vehicle in order to transmit state information to the microprocessor. A memory stores the detected values of the real-time parameters and the programs in order to define relationships between specific detected values of the real-time parameters. A display generates a signal that can be perceived by humans and relates to state information. The microprocessor is connected to the display in order to transmit a state output to the display. The microprocessor is programmed in such a way that the microprocessor continuously and automatically determines a multiplicity of unknown values relating to states of the motor vehicle as a function of the detected values of the real-time parameters. The microprocessor generates an interaction display result that determines a state of the components of the motor vehicle. An operator of the motor vehicle has direct access to information from the management system in order to permit the operator to make reasonable logical management decisions, so as to remedy costly problems and inefficiencies quickly and reliably.

WO 2014/013314 A2 discloses a device and a method that monitors, diagnosis and maintains batteries that are used to supply current to electric motors, which are used to drive vehicles.

### SUMMARY

An object of the disclosure is to permit electronically automated testing of a state of an electrical system, in particular of an electrical energy supply system, of a motor vehicle and system components of the motor vehicle.

According to the method according to the disclosure to test a state of an electrical system, in particular of an electrical energy supply system, of a motor vehicle, during testing of at least one electrical component of the system at least one electrical property of this electrical component is detected electronically during variation of at least one electric property of at least one further electrical component of the system.

According to the disclosure, measured values relating to at least one electrical property, for example a voltage value, a current value or the like, of at least one electrical component of the system are detected by varying at least one electrical property of at least one further electrical component of the system. Therefore, an electrical property of at least one electrical component of the system is not detected by applying an external load or an external source. Instead, this is done by using sources and sinks for electrical energy, which are already components of the system. For example, a light is switched on in order to increase a current of the overall system. According to the disclosure, the testing of the system can therefore be carried out by performing electronic open-loop and/or closed-loop operation control of at least one electrical component of the system, and simultaneously measuring at least one electrical parameter of at least one further electrical component of the system. In this context, individual electrical components can be correspondingly open-loop and/or closed-loop controlled in chronological succession while electrical parameters of other electrical components are detected electronically. This permits functionality of the components to be checked and faults to be detected.

The result of testing of the electrical system can be presented graphically via a display unit, in order to be able to provide a person with information about a state of the entire system, or parts of the system. By testing the electrical system, possible errors in the system or components thereof can be diagnosed. The testing of the system can be carried out on request, or automatically, at specific predefined times. The testing can be repeated, with a result that the same test results and measures are obtained. After a conclusion of the testing, a complete test report can be generated and output, or stored. The testing can already be used in development of motor vehicles. The testing can be adapted to various motor vehicles or various original manufacturers and various vehicle architectures. The testing permits automated identification of faults in the system.

According to one advantageous refinement, there is provision that the individual electrical components of the system are detected electronically, and a deterministic test sequence that sequentially tests the individual electrical components, on the basis of the electrical components present, is generated electronically, wherein the test sequence is carried out electronically in an automated fashion. As a result, comparable tests on similarly equipped motor vehicles can take place. In addition, the testing can be adapted by automated detection of the electrical components of the system and automated ordering of test steps into a specific sequence of different system configurations or motor vehicle configurations. The testing is very robust since test steps of the test sequence are not varied. All the variations of the test sequence originate solely from varying a composition of the system to be tested, with a result that only a type and/or number of test steps that are defined in a uniform fashion is varied. Therefore, variations within the test result can be interpreted as variations of the electrical system.

Individual test states of the system and/or of the motor vehicle, on the one hand, and/or state transitions between the test states, on the other, to test the individual electrical components are advantageously defined electronically on the basis of the individual electrical components of the system, and are optionally implemented electronically in an automated fashion in individual test steps of sequential testing. The motor vehicle can be “run” electronically in an automated fashion through the individual test states and the state transitions. The test steps can be repeated. In addition, variations of state transitions can be carried out. All these measures can be resumed, with a result that the individual test steps can be assigned data that is detected or determined and relate to the electrical properties of the electrical components. It is advantageous for the automated implementation of the individual test states of the system and/or of state transitions between the test states to test the individual electrical components of the system if individual components of the system can be selectively influenced in terms of their functionality (for example, “switching on,” “switching off,” “setting of deterministic operating states,” etc. . . . ) and therefore the functionality thereof can be checked.

It is also advantageous if a number of the test states and/or state transitions that are to be implemented during the sequential testing are/is increased in case of a faulty system. As a result, the testing can be concentrated on specific electrical components that are assigned a fault. In addition, a sampling rate can be increased during the concentrated testing. Intermittent detection of faults by repeatedly carrying out the testing can find faults that are caused, for example, by poor electrical connections and corrosion on cables.

According to a further advantageous refinement, there is provision that during a test step, a rotational speed of an engine of the motor vehicle and/or a voltage setpoint value for a dynamo of the motor vehicle are/is varied, and/or that a battery of the motor vehicle is charged and/or discharged, and/or that at least one electrical component is switched on and/or off, and/or that at least one electrical component is operated in a specific state, and/or that power values of a starter of the motor vehicle are detected. For example, electrical components such as lights, a radio, an air-conditioning system, a blower, windscreen wipers, a heating system and the like can be switched on and/or off, or else switched into specific operating states (e.g. blower, air-conditioning system, lights).

According to a further advantageous refinement, the electrical properties of the electrical components of the system are synchronized with data from a database that contains predefined electrical properties of the electrical components and/or test data relating to the electrical components and/or maintenance data relating to the electrical components. As a result, the testing can be based on the information that is contained in the database and relates to the electrical components of the system, which are actually present. Alternatively or additionally, the electrical properties of the electrical components of the system can be used to update the information contained in the database. A connection to the database can be cableless or cable-bound. The database can be a database of an original manufacturer of individual electrical components or of the entire system.

A result of the testing of the system is advantageously loaded into the database. As a result, statistical evaluation of the test results contained in the database can be carried out, for example in order to determine fault sources within a specific vehicle fleet.

According to a further advantageous refinement, the result of the testing of the system is compared with at least one test result that is contained in the database, and a degree of wear of the system is determined based on a result of this comparison between the result of the testing of the system and the at least one test result.

According to a further advantageous refinement, a prediction of faults of the system and/or a time for at least one electrical component to be changed is made on the basis of the result of the comparison.

According to a further advantageous refinement, at least one electrical property of at least one electrical component of the system is detected by at least one separate sensor. With the sensor, additional external measurement can take place in order to refine the test results. The sensor can comprise a current clamp for specific electrical components, with the result that, for example, the current and the voltage level can be measured directly at the respective electrical component.

A positioning of the sensor is advantageously defined based on the result of the testing of the system.

According to a further advantageous refinement, external evaluation electronics or vehicle-specific electronics are used to carry out the method. When vehicle-specific electronics are used, continuous monitoring of the state of the electrical system can be carried out.

In the text which follows, the disclosure will be explained by way of example with reference to the appended FIGURE and using a preferred embodiment, wherein the features specified below can, when considered respectively per se as well as in a different combination of at least two of these refinements with one another, form an advantageous or developing aspect of the disclosure. In the drawings:

### BRIEF DESCRIPTION OF THE DRAWINGS

The FIGURE shows a flowchart of an exemplary embodiment for a method according to the disclosure to test a state of an electrical energy supply system of a motor vehicle.

### DETAILED DESCRIPTION

As required, detailed embodiments of the present disclosure are disclosed herein; however, it is to be understood that the disclosed embodiments are merely exemplary of the disclosure that may be embodied in various and alternative forms. The figures are not necessarily to scale; some features may be exaggerated or minimized to show details of particular components. Therefore, specific structural and functional details disclosed herein are not to be interpreted as limiting, but merely as a representative basis for teaching one skilled in the art to variously employ the present disclosure.

In step 100, electronics, which are used to carry out testing, are connected to the electrical system of the motor vehicle. The electronics can be external evaluation electronics or vehicle-specific electronics.

In order to configure the testing, which is to be carried out with the electronics, the individual electrical components of the system are detected electronically in step 200.

In step 300, the electrical properties of the electrical components of the system are synchronized with data from a database that contains predefined electrical properties of the electrical components and/or test data relating to the electrical components and/or maintenance data relating to the electrical components.

In step 400, a deterministic test sequence generated from sequential testing of the individual electrical components is generated electronically on the basis of the electrical components that are present. In this context, individual test states of the system and/or of the motor vehicle, on the one hand, and/or state transitions between the test states, on the other, to test the individual electrical components, can be defined electronically based on the individual electrical components of the system.

Taking step 400 as a starting point for the entire electrical system being tested, and in step 500 the test sequence is carried out electronically in an automated fashion. Alternatively, in step 600, the testing is carried out only on a number of electrical components of the system. Alternatively, in step 700, the testing is carried out only on a number of electrical components of the system, measured values of separate external sensors being additionally taken into account. For this purpose, electrical properties of the electrical components are detected in step 710 by separate sensors. Positioning of the sensors can be defined in step 720 on the basis of a composition of the system detected in step 200.

In step 800, during the testing of the electrical components of the system, at least one electrical property of at least one electrical component is detected electronically during variation of at least one electrical property of at least one further electrical component of the system. In this context, the test states of the system and/or of the motor vehicle, which are defined in step 400, on the one hand, and/or state transitions between the test states, on the other, are optionally implemented electronically in an automated fashion in individual test steps of the sequential testing. During such a test step, a rotational speed of an engine of the motor vehicle and/or a voltage setpoint value for a dynamo of the motor vehicle can be varied and/or a battery of the motor vehicle can be charged and/or discharged and/or at least one electrical component can be switched on and/or off, and/or at least one electrical component can be operated in a specific state, and/or power values of a starter of the motor vehicle can be detected. In this context, a power consumption behavior of an electrical component to be tested can be detected. The individual test steps can be carried out when an ignition is switched on and off. A maximum outputting of the dynamo can be detected at specific rotational speeds of the engine. The rated value of a voltage of the dynamo can be varied in order to test a regulator operation of regulators of the dynamo.

In step 900, all the relevant states and parameters of the system or of specific electrical components thereof are detected. As a result, changes in the detected values compared to anticipated values can be detected. If, for example, a drop in current below an anticipated value occurs when a light is switched on, it can be inferred that a lamp or the like is defective. The detected data can be displayed on a display unit in real time.

In method step 910, a test report can be produced and stored. The test report, which represents the result of the testing of the system, can be loaded into the database. The system can move from step 910 to step 500, 600 or 700, in order to repeat the testing or to carry out other types of testing.

In step 920, the result of the testing of the system can be compared with at least one test result that is contained in the database. On the basis of a result of this comparison between the result and the at least one test result, it is possible to determine a degree of wear of the system. In addition, on the basis of a result of the comparison, it is possible to predict faults in the system and/or a time for at least one electrical component to be replaced.

While exemplary embodiments are described above, it is not intended that these embodiments describe all possible forms of the disclosure. Rather, the words used in the specification are words of description rather than limitation, and it is understood that various changes may be made without departing from the spirit and scope of the disclosure. Additionally, the features of various implementing embodiments may be combined to form further embodiments of the disclosure.

What is claimed is:

1. A method to test a state of an electrical energy supply system of a motor vehicle comprising:
testing at least one electrical component of the energy supply system; and
detecting at least one electrical property of the electrical component electronically during variation of at least one electrical property of at least one further electrical component of the system.

2. The method as claimed in claim 1, wherein the at least one electrical component including a plurality of individual electrical component of the system, and further comprising:
electronically detecting the individual electrical components of the system; and
electronically generating a deterministic test sequence for sequentially testing the individual electrical components responsive to detecting the electrical components that are present, wherein the test sequence is carried out electronically in an automated fashion.

3. The method as claimed in claim 2 further comprising implementing, in an automated fashion, defined individual test states of the motor vehicle and state transitions between the test states to test the individual electronic components in individual test steps of the test sequence.

4. The method as claimed in claim 3 further comprising implementing a number of the test states and state transitions the test sequence, wherein the number is increased in a faulty system.

5. The method as claimed in claim 3, wherein the individual test steps include varying a rotational speed of an engine, varying a voltage setpoint value for a dynamo, charging or discharging a battery, switching on and off at least one electrical component, operating at least one electrical component in a specific state, and detecting power values of a starter of the motor vehicle are detected.

6. The method as claimed in claim 1 further comprising influencing individual components of the system to check a function of each of the individual components.

7. The method as claimed in claim 2 further comprising synchronizing electrical properties of the individual electrical components with data from a database that contains predefined electrical properties, test data, and maintenance data of the individual electrical components.

8. The method as claimed in claim 7 further comprising loading a result of the testing of the system into the database.

9. The method as claimed in claim 8 further comprising comparing the result with at least one test result that is contained in the database to determine a degree of wear of the system.

10. The method as claimed in claim 9 further comprising predicting faults of the system and a time for at least one electrical component to be changed based on the result of the comparing.

11. The method as claimed in claim 1, wherein the at least one electrical property of at least one electrical component of the system is detected via at least one sensor.

12. The method as claimed in claim 11 further comprising positioning the sensor based on the result of the testing of the system.

13. An electrical energy supply system comprising:
sensors that detect an electrical property of an electrical component during variation of a further electrical property of a further electrical component; and
electronics configured to electronically generate an automated deterministic test sequence that sequentially tests individual electrical components against the electrical and further electrical components such that individual test steps of the test sequence implement defined individual test states and transitions between the test states to test the individual electronic components.

14. The electrical energy supply system as claimed in claim 13, wherein the electronics are configured to synchronize electrical properties of the individual electrical components with data from a database that contains predefined electrical properties, test and maintenance data, and a test result of the test sequence.

15. The electrical energy supply system as claimed in claim 14, wherein the electronics are configured to determine a degree of wear based on a comparison of the result with at least one test result that is contained in the database.

16. The electrical energy supply system as claimed in claim 14, wherein the electronics are configured to predict system faults and a time for at least one electrical component to be changed based on a comparison result of the comparison.

17. A vehicle comprising:
sensors that detect electrical components and further electrical components; and
an energy supply system configured to electronically generate an automated deterministic test sequence that sequentially tests individual electrical components against the electrical components and further electrical components such that individual test steps of the test sequence implement defined individual test states and transitions between the test states to test the individual electronic components.

18. The vehicle as claimed in claim 17, wherein the system synchronizes electrical properties of the individual electrical components with data from a database that contains predefined electrical properties, test and maintenance data, and a result of the test sequence.

19. The vehicle as claimed in claim 18, wherein the system determines a degree of wear based on a comparison of the result with a test result stored in the database.

20. The vehicle as claimed in claim 19, wherein the system predicts faults and a time for at least one electrical component to be changed based on a comparison result of the comparison.
